(19) United States
(12) Patent Application Publication
(10) Pub. No.: US 2025/0219605 A1
(43) Pub. Date: Jul. 3, 2025

(54) ANALOG STORAGE USING MEMORY DEVICE

(71) Applicant: ANHUI ANUKI TECHNOLOGIES CO., LTD., Hefei, Anhui (CN)

(72) Inventors: Wei CHENG, Hefei, Anhui (CN); Chengjie ZUO, Hefei, Anhui (CN); Jun HE, Hefei, Anhui (CN)

(21) Appl. No.: 18/850,528

(22) PCT Filed: Dec. 6, 2022
(86) PCT No.: PCT/CN2022/136904

§ 371 Date: Sep. 24, 2024

(30) Foreign Application Priority Data
Mar. 25, 2022 (CN) 202210305981.5

(51) Int. Cl. H03H 7/01; H03H 7/46; H03H 9/70

(52) U.S. Cl. CPC H03H 7/0115; H03H 7/1758; H03H 7/1783; H03H 7/46; H03H 9/70

(57) ABSTRACT

A resonator includes an LC resonant unit and an embedded resonant unit. The LC resonant unit includes a resonant element. The resonant element includes a first portion, a second portion, and an interface between the first portion and the second portion. The first portion is connected to the second portion through the interface. The embedded resonant unit is embedded in the LC resonant unit through the interface.

This application claims priority to Chinese Patent Application No. 202210305981.5 filed Mar. 25, 2022, the disclosure of which is incorporated herein by reference in its entirety.

### TECHNICAL FIELD

Embodiments of the present application relate to the field of signal processing technology, for example, a resonator, a filter, and a multiplexer.

### BACKGROUND

Filters are widely used in integrated circuits. A filter in a traditional integrated circuit has the following drawback: The space in the integrated circuit for placing the filter is limited, making it difficult to improve the performance of the filter. A resonator is a basic unit in the design of a filter. That is, a filter may include multiple resonators. In general, a resonator is a two-port device. Exemplarily, FIG. 1 is a circuit diagram of a resonator according to the related art. As shown in FIG. 1, the resonator includes a first inductor L1 and a first capacitor C1, and the first inductor L1 and the first capacitor C1 are connected in series to form the resonator. FIG. 2 is a circuit diagram of another resonator according to the related art. As shown in FIG. 2, the resonator includes a first inductor L1 and a first capacitor C1, and the first inductor L1 and the first capacitor C1 are connected in parallel to form the resonator. FIG. 3 is a circuit diagram of another resonator according to the related art. As shown in FIG. 3, the resonator includes a first inductor L1, a first capacitor C1, and a second capacitor C2, and the first inductor L1 and the first capacitor C1 are connected in parallel and then are connected to the second capacitor C2 in series to form the resonator. FIGS. 1 to 3 are merely each an example of a resonator. In another resonator, an inductor or a capacitor may be added additionally on the basis of a first inductor L1 and a first capacitor C1 to form a resonator.

When a filter includes multiple resonators, the resonators may be connected to each other in series or in parallel. FIG. 4 is a circuit diagram of a filter according to the related art. As shown in FIG. 4, the filter may include a first resonator A and a second resonator B. The first resonator A is connected in series between a first end IN of the filter and a second end OUT of the filter. The second resonator B is connected to the second end OUT of the filter in parallel. Therefore, a resonator in the filter may be connected in series or in parallel in the filter. In this case, the connection manner of each resonator in the filter is relatively fixed. Moreover, the filtering performance of the first resonator A and the filtering performance of the second resonator B affect the filtering performance of the filter directly. Furthermore, when different resonators are connected in series or in parallel in the filter, the resonators and the connection structures of the resonators occupy a relatively large space, not facilitating the integration of the filter.

### SUMMARY

The present application provides a resonator, a filter, and a multiplexer to improve the filtering effect of the resonator and save the occupation space of the resonator.

Embodiments of the present application provide a resonator. The resonator includes an LC resonant unit and an embedded resonant unit.

The LC resonant unit includes a resonant element. The resonant element includes a first portion, a second portion, and an interface between the first portion and the second portion. The first portion is connected to the second portion through the interface. The embedded resonant unit is embedded in the LC resonant unit through the interface.

Optionally, the resonant element is an inductive element. The interface is disposed in a middle of the inductive element. The inductive element is divided into the first portion and the second portion through the interface.

Optionally, the resonant element includes at least a first capacitive element and a second capacitive element. The first capacitive element and the second capacitive element are connected in series and form the interface at a serial connection point. The first capacitive element serves as the first portion. The second capacitive element serves as the second portion.

Optionally, the interface includes a first interface and a second interface. The embedded resonant unit is connected in series between the first interface and the second interface.

Optionally, a first end of the embedded resonant unit is connected to the interface. A second end of the embedded resonant unit is connected to a reference potential end.

Optionally, the resonant element in the LC resonant unit is same as or different from a resonant element in the embedded resonant unit.

Optionally, the embedded resonant unit at least includes an inductive element and/or a capacitive element, or the embedded resonant unit includes at least one of a surface acoustic wave (SAW) resonator and a film bulk acoustic resonator (FBAR).

Embodiments of the present application further provide a filter including the resonator described in embodiments of the present application.

Embodiments of the present application further provide a multiplexer including the filter described in embodiments of the present application.

### BRIEF DESCRIPTION OF DRAWINGS

FIG. 1 is a circuit diagram of a resonator according to the related art.

FIG. 2 is a circuit diagram of another resonator according to the related art.

FIG. 3 is a circuit diagram of another resonator according to the related art.

FIG. 4 is a circuit diagram of a filter according to the related art.

FIG. 5 is a circuit diagram of a resonator according to embodiments of the present application.

FIG. 6 is a circuit diagram of another resonator according to embodiments of the present application.

FIG. 7 is a circuit diagram of another resonator according to the related art.

FIG. 8 is a circuit diagram of another resonator according to embodiments of the present application.

FIG. 9 is a diagram illustrating the comparison between the filtering performance of the resonator provided in FIG. 7 and the filtering performance of the resonator provided in FIG. 8.

FIG. 10 is a circuit diagram of another resonator according to embodiments of the present application.

FIG. 11 is a circuit diagram of another resonator according to embodiments of the present application.

FIG. 12 is a structural diagram of a multiplexer according to embodiments of the present application.

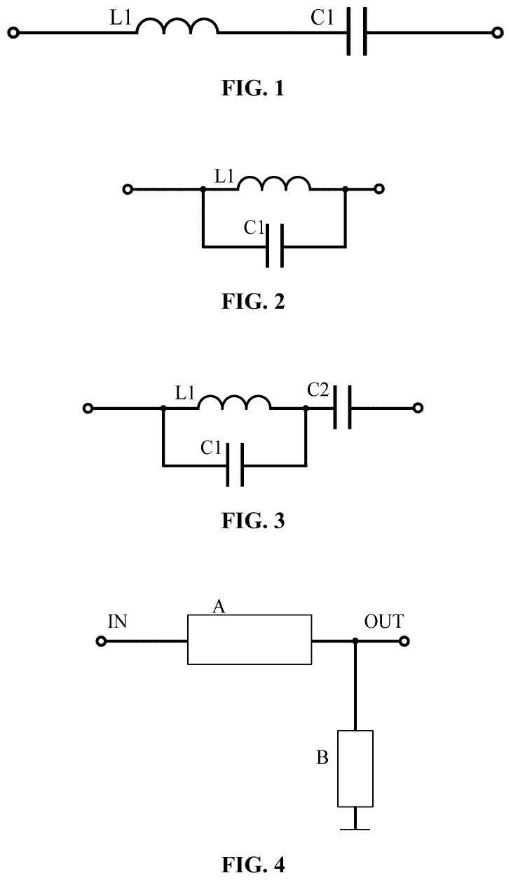

### DETAILED DESCRIPTION

The present application is described below in conjunction with drawings and embodiments. It is to be understood that specific embodiments described herein are intended to illustrate the present application and not to limit the present application. Additionally, it is to be noted that only part, not all, of structures related to the present application are illustrated in the drawings.

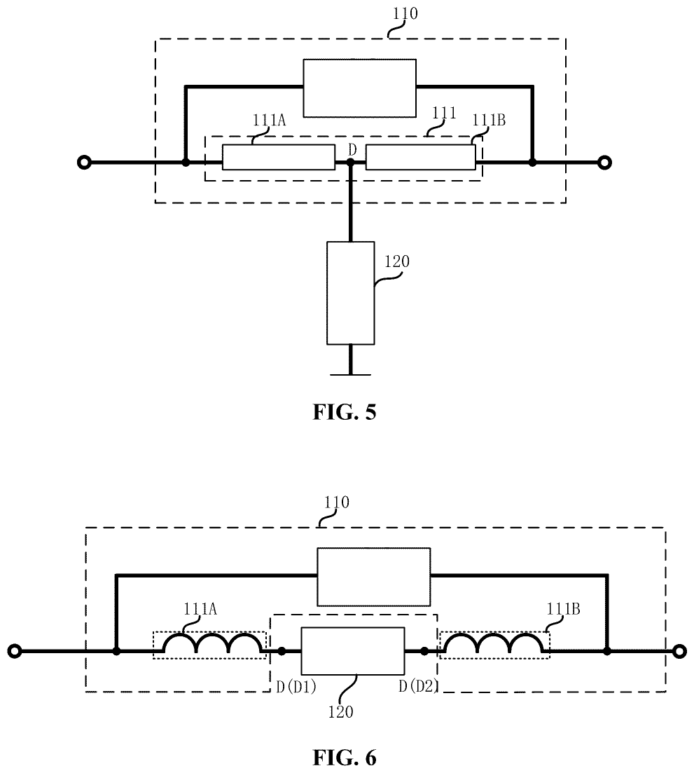

FIG. 5 is a circuit diagram of a resonator according to embodiments of the present application. As shown in FIG. 5, the resonator includes at least one LC resonant unit 110 and at least one embedded resonant unit 120. The at least one LC resonant unit 110 includes at least one resonant element 111. One of the at least one resonant element 111 includes a first portion 111A, a second portion 111B, and an interface D between the first portion 111A and the second portion 111B. The first portion 111A is connected to the second portion 111B through the interface D. The at least one embedded resonant unit 120 is embedded in the at least one LC resonant unit 110 through the interface D.

FIG. 5 exemplarily illustrates that the resonator includes one LC resonant unit 110 and one embedded resonant unit 120. The LC resonant unit 110 is composed of an inductive element and a capacitive element. Exemplarily, the LC resonant unit 110 is composed of one inductive element and one capacitive element that are connected in parallel. A resonant element 111 may be an inductive element or a capacitive element connected in series. The resonant element 111 may be divided into the first portion 111A and the second portion 111B through the interface D. The first portion 111A is connected to the second portion 111B through the interface D so that the resonant element 111 serves as a whole. When the resonant element 111 is provided with the interface D, the embedded resonant unit 120 may be connected to the interface D so that the embedded resonant unit 120 is embedded in the LC resonant unit 110 through the interface D. In this manner, the LC resonant unit 110 and the embedded resonant unit 120 each serve as a part of the resonator and filter input signals, guaranteeing the filtering performance of the resonator. Moreover, the embedded resonant unit 120 is embedded in the LC resonant unit 110 through the interface D to enable an element in the embedded resonant unit 120 and an element in the LC resonant unit 110 to form a new resonant unit so that the input signals are filtered through the new resonant unit. Therefore, the filtering effect of the resonator is improved, a number of signal transmission zeros of the resonator is increased, and further the filtering performance of the resonator is improved.

It is to be noted that FIG. 5 is an example of the resonator. In other embodiments, the LC resonant unit 110 may also be composed of one inductive element and one capacitive element that are connected in series. The resonator may also include multiple LC resonant units 110 and/or multiple embedded resonant units 120. The multiple LC resonant units 110 may be connected in series and/or in parallel. The embedded resonant units 120 may be embedded in different LC resonant units 110. Alternatively, different embedded resonant units 120 may be connected to each other and then embedded into an LC resonant unit 110. Additionally, the number and connection relationship of inductive elements and capacitive elements in each LC resonant unit 110 may be the same or different. Similarly, the number and connection relationship of resonant elements in each embedded resonant unit 120 may be the same or different.

According to the technical solutions in the embodiments, the interface is disposed on the resonant element in the LC resonant unit so that the embedded resonant unit is connected to the LC resonant unit through the interface. In this case, the LC resonant unit and the embedded resonant unit can filter the input signals simultaneously, guaranteeing the filtering performance of the resonator. Moreover, an element in the embedded resonant unit and an element in the LC resonant unit form a new resonant unit so that the input signals are filtered through the new resonant unit. Therefore, the filtering effect of the resonator is improved, a number of signal transmission zeros of the resonator is increased, and further the filtering performance of the resonator is improved.

Exemplarily, FIG. 6 is a circuit diagram of another resonator according to an embodiment of the present application. As shown in FIG. 6, the resonant element 111 is an inductive element. The interface D is disposed in the middle of the inductive element. The inductive element is divided into the first portion 111A and the second portion 111B through the interface D.

The resonant element 111 may be an inductive element. The interface D is disposed in the middle of the inductive element so that the inductive element can be divided into the first portion 111A and the second portion 111B through the interface D. Then the embedded resonant unit 120 is connected in the interface D so that the embedded resonant unit 120 is embedded in the LC resonant unit 110 through the interface D on the inductive element. Moreover, an element in the embedded resonant unit 120 and an element in the LC resonant unit 110 form a new resonant unit so that input signals are filtered through the new resonant unit. Therefore, the filtering effect of the resonator is improved, a number of signal transmission zeros of the resonator is increased, and further the filtering performance of the resonator is improved. Moreover, the first portion 111A of the inductive element is connected to the second portion 111B of the inductive element through the interface D so that the entire inductive value of the inductive element is unchanged, guaranteeing the performance of the resonator and facilitating the design of the resonator.

Exemplarily, the inductive element may be an inductor. The inductor and the capacitive element are in the LC resonant unit 110 and are connected in parallel. Then one inductor may be designed in the design of the LC resonant unit 110. Moreover, the interface D is formed in the middle of the inductor for embedding the embedded resonant unit 120, thereby reducing the entire occupation space of the inductor and the embedded resonant unit 120 and thus saving the occupation space of the resonator. Exemplarily, in the forming of the inductor, when the inductor is a three-dimensional inductor structure, the inductor includes at least two conductive layers. Multiple conductive layers are electrically connected to each other to form the inductor. In this case, the interface D may be disposed at a junction between the different conductive layers. When the inductor is a two-dimensional inductor structure, the inductor may include multiple coils. The interface D may be disposed at a junction between different coils.

When the interface D is disposed in the middle of the inductive element, the embedded resonant unit 120 may be connected to the LC resonant unit 110 in series or in parallel.

With continued reference to FIG. 6, FIG. 6 exemplarily illustrates that the interface D includes a first interface D1 and a second interface D2. The embedded resonant unit 120 is connected in series between the first interface D1 and the second interface D2.

The embedded resonant unit 120 may be connected to the LC resonant unit 110 in series. In this case, the first interface D1 is connected to a first end of the embedded resonant unit 120. The second interface D2 is connected to a second end of the embedded resonant unit 120. The first portion 111A is connected to the second portion 111B through the embedded resonant unit 120. The entire inductive value of the first portion 111A and the second portion 111B is a sum of the inductive value of the first portion 111A and the inductive value of the second portion 111B. That is, the entire inductive value of the first portion 111A and the second portion 111B is unchanged. Moreover, through an embedded connection to the embedded resonant unit 120, an element in the embedded resonant unit 120 and an element in the LC resonant unit 110 form a new resonant unit so that the input signals are filtered through the new resonant unit. Therefore, the filtering effect of the resonator is improved, a number of signal transmission zeros of the resonator is increased, and further the filtering performance of the resonator is improved.

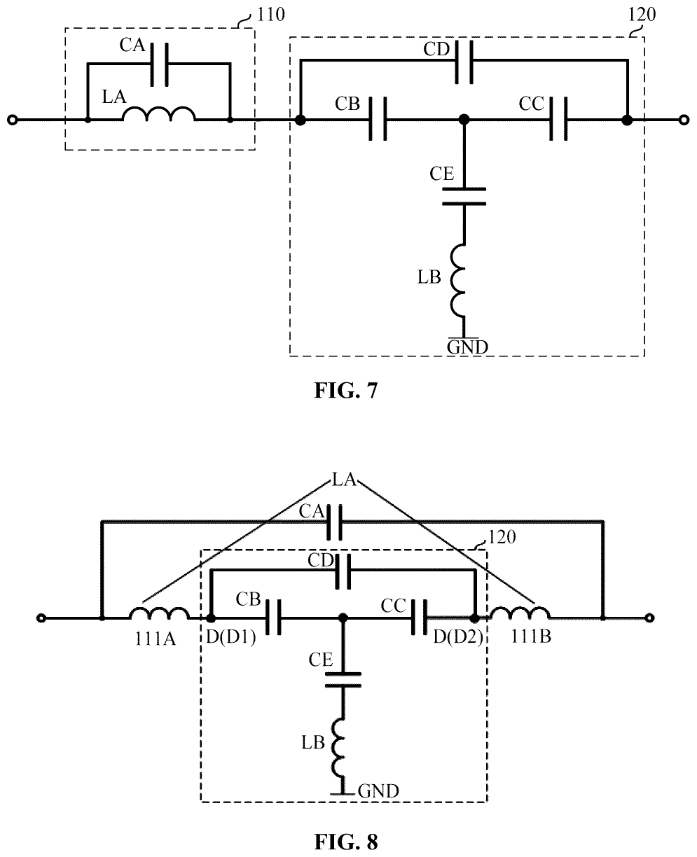

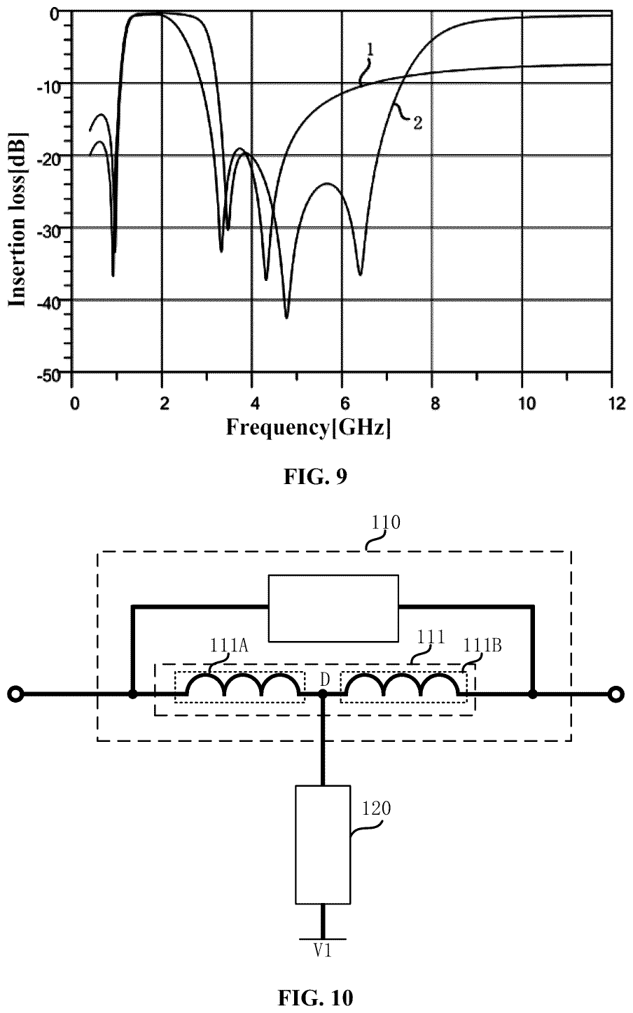

Exemplarily, FIG. 7 is a circuit diagram of another resonator according to the related art. FIG. 8 is a circuit diagram of another resonator according to embodiments of the present application. FIG. 9 is a diagram illustrating the comparison between the filtering performance of the resonator provided in FIG. 7 and the filtering performance of the resonator provided in FIG. 8. The abscissa represents frequency. The ordinate represents insertion loss. Curve 1 is a performance curve of the resonator provided in the related art. Curve 2 is a performance curve of the resonator provided in the embodiments of the present application. As shown in FIGS. 7 to 9, the LC resonant unit 110 in the resonator includes an A inductor LA and an A capacitor CA that are connected in parallel. The embedded resonant unit 120 includes a B capacitor CB, a C capacitor CC, a D capacitor CD, an E capacitor CE, and a B inductor LB. The B capacitor CB and the C capacitor CC are connected in series between the first end of the embedded resonant unit 120 and the second end of the embedded resonant unit 120. The D capacitor CD is connected in parallel with the B capacitor CB and the C capacitor CC. A first end of the E capacitor CE is connected to a series connection point of the B capacitor CB and the C capacitor CC. A second end of the E capacitor CE is connected to a first end of the B inductor LB. A second end of the B inductor LB is connected to a reference potential end. FIGS. 7 and 8 exemplarily illustrate that the reference potential end is a reference ground GND. In the related art, as shown in FIG. 7, the LC resonant unit 110 and the embedded resonant unit 120 are connected in series. In this embodiment, as shown in FIG. 8, the first interface D1 and the second interface D2 are disposed on the A inductor LA of the LC resonant unit 110. The embedded resonant unit 120 is connected in series between the first interface D1 and the second interface D2. It can be seen from curve 1 and curve 2 that the roll-off slope of curve 2 is greater than the roll-off slope of curve 1 on a side greater than the passband frequency range. That is, the steepness of curve 2 is greater than the steepness of curve 1. Therefore, the filtering effect of the resonator provided in this embodiment is better than the filtering effect of the resonator provided in the related art. Moreover, curve 2 has an additional transmission zero compared with curve 1, further improving the filtering effect of the resonator provided in this embodiment. Accordingly, the arrangement in which the embedded resonant unit 120 is embedded in the LC resonant unit 110 through the interface D, on the basis of the resonator provided in the related art, can improve the filtering effect of the resonator, increase the number of signal transmission zeros of the resonator, and further improve the filtering performance of the resonator.

FIG. 10 is a circuit diagram of another resonator according to embodiments of the present application. As shown in FIG. 10, the first end of the embedded resonant unit 120 is connected to the interface D. The second end of the embedded resonant unit 120 is connected to the reference potential end V1.

The embedded resonant unit 120 may also be accessed to the resonator in a parallel connection manner. That is, the first end of the embedded resonant unit 120 is connected to the interface D, and the second end of the embedded resonant unit 120 is connected to the reference potential end V1. In this case, the first portion 111A is connected to the second portion 111B through the interface D. The entire inductive value of the first portion 111A and the second portion 111B is still unchanged. Moreover, through an embedded connection to the embedded resonant unit 120, an element in the embedded resonant unit 120 and an element in the LC resonant unit 110 form a new resonant unit so that the input signals are filtered through the new resonant unit. Therefore, the filtering effect of the resonator is improved, a number of signal transmission zeros of the resonator is increased, and further the filtering performance of the resonator is improved. Exemplarily, the reference potential end V1 may be a reference ground or an input of another reference potential.

It is to be noted that the embedded resonant unit 120 may also be connected to another circuit or element through the reference potential end V1 to improve the filtering performance of the resonator. Exemplarily, the second end of the embedded resonant unit 120 may be connected to another resonator to form a filter to improve the filtering performance of the filter.

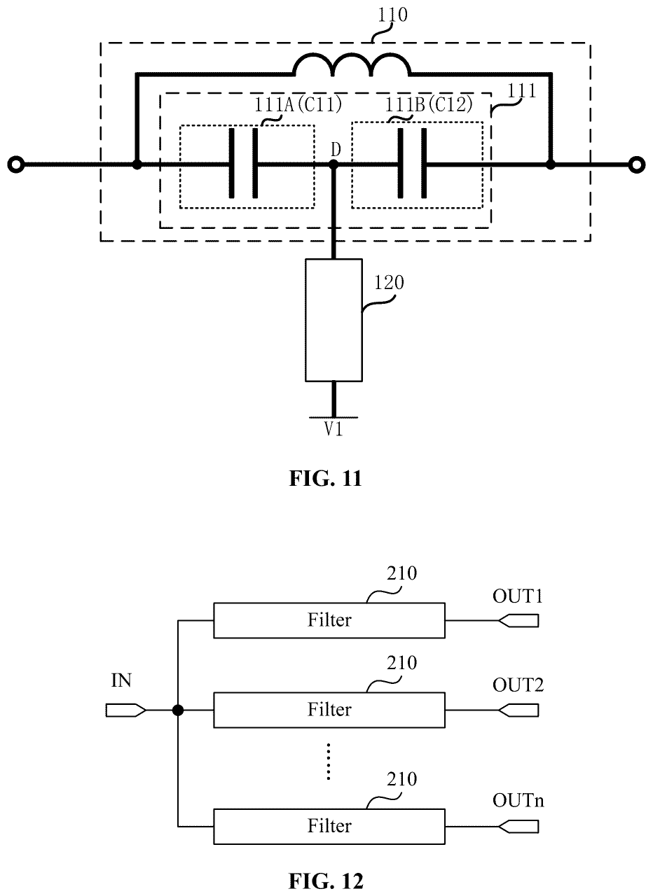

FIG. 11 is a circuit diagram of another resonator according to an embodiment of the present application. As shown in FIG. 11, the resonant element 111 includes at least a first capacitive element C11 and a second capacitive element C12. The first capacitive element C11 and the second capacitive element C12 are connected in series and form the interface D at a serial connection point. The first capacitive element C11 serves as the first portion 111A. The second capacitive element C12 serves as the second portion 111B.

As shown in FIG. 11, when the resonant element 111 is a capacitive element, the capacitive element may be two capacitive elements connected in series. Then the interface D is formed at the series connection point of the two capacitive elements so that the embedded resonant unit 120 is embedded in the LC resonant unit 110 through the interface D between the capacitive elements. Therefore, an element in the embedded resonant unit 120 and an element in the LC resonant unit 110 form a new resonant unit so that the input signals are filtered through the new resonant unit. In this manner, the filtering effect of the resonator is improved, a number of signal transmission zeros of the resonator is increased, and further the filtering performance of the resonator is improved. Moreover, the interface D is formed at the series connection point of the first capacitive element C11 and the second capacitive element C12, guaranteeing that the capacitive value of the first capacitive element C11 and the capacitive value of the second capacitive element C12 are unchanged, thereby guaranteeing that the entire capacitive value of the first capacitive element C11 and the second capacitive element C12 are unchanged, guaranteeing the performance of the resonator, and facilitating the design of the resonator. Exemplarily, the first capacitive element C11 and the second capacitive element C12 may be each a capacitor.

When the first capacitive element C11 and the second capacitive element C12 are connected in series and the interface D is formed at the series connection point, the embedded resonant unit 120 may also be connected to the LC resonant unit 110 in series or in parallel. When the embedded resonant unit 120 and the LC resonant unit 110 are connected in series, the interface D may include the first interface and the second interface, the embedded resonant unit 120 is connected in series between the first interface and the second interface, and the first capacitive element C11 is connected to the second capacitive element C12 through the embedded resonant unit 120. When the embedded resonant unit 120 and the LC resonant unit 110 are connected in parallel, the first end of the embedded resonant unit 120 is connected to the interface D, and the second end of the embedded resonant unit 120 is connected to the reference potential end.

On the basis of the preceding multiple technical solutions, the resonant element in the LC resonant unit 110 is the same as or different from a resonant element in the embedded resonant unit 120.

The resonant element in the LC resonant unit 110 may be set to be the same as or different from the resonant element in the embedded resonant unit 120 according to the performance requirements of the resonator. When the resonant element in the LC resonant unit 110 is the same as the resonant element in the embedded resonant unit 120, the resonant element in the embedded resonant unit 120 includes only inductive elements and capacitive elements, and the number and connection relationship of inductive elements and capacitive elements are the same as the number and connection relationship of inductive elements and capacitive elements in the LC resonant unit 110. That is, the LC resonant unit 110 is entirely the same as the embedded resonant unit 120. When the resonant element in the LC resonant unit 110 is different from the resonant element in the embedded resonant unit 120, the embedded resonant unit 120 may include an element other than inductive elements and capacitive elements. Alternatively, the number and/or connection relationship of inductive elements and capacitive elements are different from the number and/or connection relationship of inductive elements and capacitive elements in the LC resonant unit 110.

On the basis of the preceding multiple technical solutions, the embedded resonant unit 120 at least includes an inductive element and/or a capacitive element. Alternatively, the embedded resonant unit 120 includes at least one of a surface acoustic wave resonator and a film bulk acoustic resonator.

The embedded resonant unit 120 may include resonant elements of multiple types as long as the performance requirements of the resonator are met. Exemplarily, the embedded resonant unit 120 may include just an inductive element or a capacitive element. In this case, the inductive element or capacitive element may serve as a special resonant element to be embedded in the LC resonant unit 110. Alternatively, the embedded resonant unit 120 may include both an inductive element and a capacitive element. In this case, the embedded resonant unit 120 is an LC resonator. In other embodiments, the embedded resonant unit 120 may further include at least one of a surface acoustic wave (SAW) resonator or a film bulk acoustic resonator (FBAR).

Embodiments of the present application further provide a filter. The filter includes the resonator provided in any embodiment of the present application.

The filter includes at least the resonator provided in any embodiment of the present application and thus has the effect of the resonator, which is not repeated here. Additionally, the filter may also include other filter circuits for improving the filtering function of the filter. Exemplarily, other filter circuits may be low pass filter circuits, high pass filter circuits, or band pass filter circuits, which is not limited in embodiments of the present application.

Embodiments of the present application also provide a multiplexer. FIG. 12 is a structural diagram of a multiplexer according to embodiments of the present application. As shown in FIG. 12, the multiplexer includes the filter 210 provided in any embodiment of the present application.

With continued reference to FIG. 12, the multiplexer includes one first end IN and at least two second ends. Each filter 210 is connected in series between the first end IN of the multiplexer and any second end of the multiplexer.

FIG. 12 exemplarily illustrates that the multiplexer includes one first end IN and n second ends which are denoted as OUT1, OUT2, . . . , and OUTn respectively. Each filter 210 is connected in series between the first end IN and one second end. For example, the first filter 210 is connected in series between the first end IN and the first second end OUT1, the second filter 210 is connected in series between the first end IN and the second second end OUT2, and the rest can be done in the same way. The multiplexer includes the filter 210 provided in any embodiment of the present application and thus has the effect of the filter 210, which is not repeated here.

It is to be noted that the multiplexer may also include other filter circuits connected in series between the first end IN and any second end. Other filter circuits may be low pass filter circuits, high pass filter circuits, or band pass filter circuits, which is not limited in embodiments of the present application.

1. A resonator, comprising an LC resonant unit and an embedded resonant unit, wherein
the LC resonant unit comprises a resonant element; the resonant element comprises a first portion, a second portion, and an interface between the first portion and the second portion; the first portion is connected to the second portion through the interface; and
the embedded resonant unit is embedded in the LC resonant unit through the interface.

2. The resonator according to claim 1, wherein the resonant element is an inductive element, the interface is disposed in a middle of the inductive element, and the inductive element is divided into the first portion and the second portion through the interface.

3. The resonator according to claim 1, wherein the resonant element comprises a first capacitive element and a second capacitive element, the first capacitive element and the second capacitive element are connected in series and form the interface at a serial connection point, the first capacitive element serves as the first portion, and the second capacitive element serves as the second portion.

4. The resonator according to claim 1, wherein the interface comprises a first interface and a second interface, and the embedded resonant unit is connected in series between the first interface and the second interface.

5. The resonator according to claim 1, wherein a first end of the embedded resonant unit is connected to the interface, and a second end of the embedded resonant unit is connected to a reference potential end.

6. The resonator according to claim 1, wherein the resonant element in the LC resonant unit is same as or different from a resonant element in the embedded resonant unit.

7. The resonator according to claim 6, wherein the embedded resonant unit comprises at least one of an inductive element and a capacitive element, or the embedded resonant unit comprises at least one of a surface acoustic wave resonator and a film bulk acoustic resonator.

8. A filter, comprising a resonator, wherein the resonator comprises an LC resonant unit and an embedded resonant unit;
the LC resonant unit comprises a resonant element; the resonant element comprises a first portion, a second portion, and an interface between the first portion and the second portion; the first portion is connected to the second portion through the interface; and
the embedded resonant unit is embedded in the LC resonant unit through the interface.

9. A multiplexer, comprising the filter according to claim 8.

10. The resonator according to claim 2, wherein the interface comprises a first interface and a second interface, and the embedded resonant unit is connected in series between the first interface and the second interface.

11. The resonator according to claim 3, wherein the interface comprises a first interface and a second interface, and the embedded resonant unit is connected in series between the first interface and the second interface.

12. The resonator according to claim 2, wherein a first end of the embedded resonant unit is connected to the interface, and a second end of the embedded resonant unit is connected to a reference potential end.

13. The resonator according to claim 3, wherein a first end of the embedded resonant unit is connected to the interface, and a second end of the embedded resonant unit is connected to a reference potential end.

14. The filter according to claim 8, wherein the resonant element is an inductive element, the interface is disposed in a middle of the inductive element, and the inductive element is divided into the first portion and the second portion through the interface.

15. The filter according to claim 8, wherein the resonant element comprises a first capacitive element and a second capacitive element, the first capacitive element and the second capacitive element are connected in series and form the interface at a serial connection point, the first capacitive element serves as the first portion, and the second capacitive element serves as the second portion.

16. The filter according to claim 8, wherein the interface comprises a first interface and a second interface, and the embedded resonant unit is connected in series between the first interface and the second interface.

17. The filter according to claim 14, wherein the interface comprises a first interface and a second interface, and the embedded resonant unit is connected in series between the first interface and the second interface.

18. The filter according to claim 8, wherein a first end of the embedded resonant unit is connected to the interface, and a second end of the embedded resonant unit is connected to a reference potential end.

19. The filter according to claim 8, wherein the resonant element in the LC resonant unit is same as or different from a resonant element in the embedded resonant unit.

20. The filter according to claim 19, wherein the embedded resonant unit comprises at least one of an inductive element and a capacitive element, or the embedded resonant unit comprises at least one of a surface acoustic wave resonator and a film bulk acoustic resonator.
